(19) United States
(12) Patent Application Publication
(10) Pub. No.: US 2011/0081154 A1
(43) Pub. Date: Apr. 7, 2011

(54) APPARATUS FOR DETECTING CONNECTOR CONNECTION STATE

(75) Inventor: Motoshi UEDA, Shizuoka-ken (JP)

(73) Assignees: Kabushiki Kaisha Toshiba, Tokyo (JP); Toshiba Tec Kabushiki Kaisha, Tokyo (JP)

(21) Appl. No.: 12/882,142

(22) Filed: Sep. 14, 2010

Related U.S. Application Data
(60) Provisional application No. 61/248,964, filed on Oct. 6, 2009.

(51) Int. Cl. G03G 15/00; G01R 31/04

(52) U.S. Cl. 399/13; 324/538; 399/90

(57) ABSTRACT

An apparatus detecting connection states of connectors includes plural resistors having resistance values different from each other and connected in series to each other, in which sums of at least two resistance values selected from the plural resistance values are different from each other in all combinations of the plural resistance values, and are different from the resistance value of each of the resistors, plural first connectors provided correspondingly to the respective resistors, plural second connectors connected to the first connectors and including bypass lines which bypass the respective resistors when the second connectors are connected to the first connectors, and a controller to detect connection states of the second connectors to the first connectors based on a voltage value of a detection signal flowing through the resistors and the bypass lines.

### CROSS-REFERENCE TO RELATED APPLICATION

This application is also based upon and claims the benefit of priority from U.S. provisional application 61/248,964, filed on Oct. 6, 2009; the entire contents of which are incorporated herein by reference.

### FIELD

Embodiments described herein relate generally to a technique for detecting, when plural connectors are used, connection states of the respective connectors.

### BACKGROUND

A connector is used when a signal line is connected. Specifically, a pair of connectors (a first connector and a second connector) engaging with each other are used. When plural second connectors are connected to plural first connectors, it is necessary to confirm whether each of the second connectors is normally connected to each of the first connectors.

### DESCRIPTION OF THE DRAWINGS

FIG. 1 is a view showing a circuit structure of an apparatus for detecting connection states of plural second connectors in a first embodiment.

FIG. 2 is a view showing a relation between a combination of connection states of plural second connectors and a voltage value of a detection signal.

FIG. 3 is a view showing a state where a part of a second connector is disconnected from a first connector.

FIG. 4 is a flowchart showing a process of determining connection states of second connectors.

FIG. 5 is a view showing a structure of an image processing apparatus in the first embodiment.

FIG. 6 is an outer appearance view showing a connector assembly in a second embodiment.

FIG. 7 is an outer appearance view showing the connector assembly in the second embodiment.

FIG. 8 is an exploded view of a connector assembly in a modified example of the second embodiment.

FIG. 9 is a view showing a connection structure of a connector in a third embodiment.

### DETAILED DESCRIPTION

An apparatus for detecting connection states of connectors includes plural resistors, plural first connectors, plural second connectors, and a controller. The plural resistors are connected in series to each other, and resistance values thereof are different from each other. The sums of at least two resistance values selected from the plural resistance values are different from each other in all combinations of the plural resistance values, and are different from the resistance value of each of the resistors. The first connectors are provided correspondingly to the respective resistors. The second connectors are connected to the first connectors. The second connectors includes bypass lines which bypass the respective resistors when the second connectors are connected to the first connectors. The controller detects the connection states of the second connectors to the first connectors based on a voltage value of a detection signal flowing through the resistors and the bypass lines.

Hereinafter, embodiments will be described with reference to the drawings.

### First Embodiment

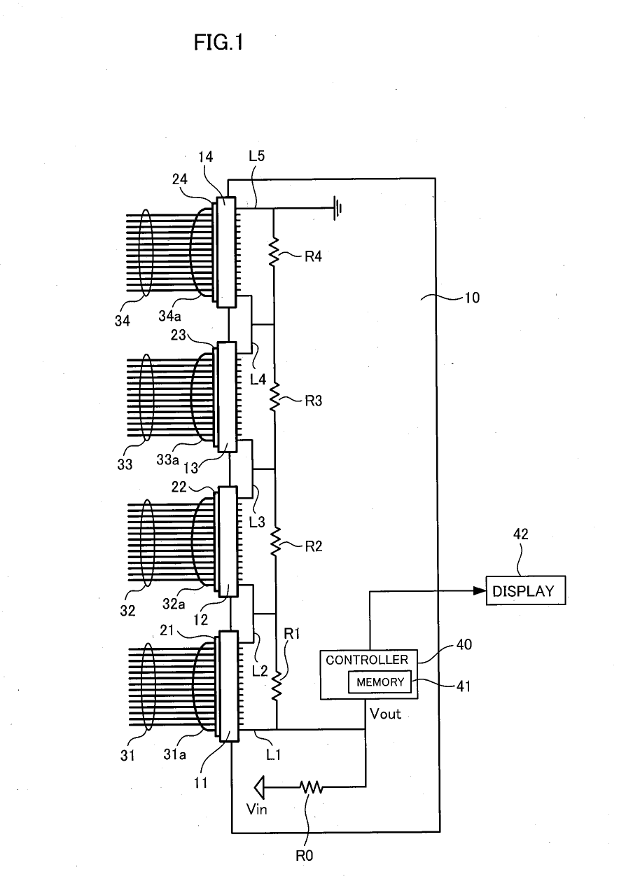

An apparatus for detecting connector connection states according to a first embodiment will be described with reference to FIG. 1. FIG. 1 is a view showing a circuit structure of the apparatus for detecting the connection states of connectors.

A circuit board 10 includes four first connectors 11 to 14. The respective first connectors 11 to 14 are connected to wirings formed on the circuit board 10. Second connectors 21 to 24 are connected to the first connectors 11 to 14. The first connectors 11 to 14 and the second connectors 21 to 24 have structures so that they can be engaged with each other. For example, the first connectors 11 to 14 have pins, and the second connectors 21 to 24 have sockets into which the pins of the first connectors 11 to 14 are inserted.

The second connectors 21 to 24 are connected with wire harnesses 31 to 34. The wire harnesses 31 to 34 have plural signal lines, and the respective signal lines are used for transmission of information. The second connectors 21 to 24 have loop signal lines (bypass lines) 31a to 34a.

When the second connector 21 is connected to the first connector 11, one end of the loop signal line 31a is connected to a wiring L1 on the circuit board 10. The wiring L1 is connected to a resistor (pull-up resistor) R0. The other end of the loop signal line 31a is connected to a wiring L2 on the circuit board 10. The wire harness 31 is connected to a signal line (not shown) on the circuit board 10. The circuit board 10 includes a resistor R1 connected in parallel to the loop signal line 31a. In other words, the loop signal line 31a bypasses the resistor R1.

When the second connector 22 is connected to the first connector 12, one end of the loop signal line 32a is connected to the wiring L2 on the circuit board 10. The other end of the loop signal line 32a is connected to a wiring L3 of the circuit board 10. The wire harness 32 is connected to a signal line (not shown) on the circuit board 10. The circuit board 10 includes a resistor R2 connected in parallel to the loop signal line 32a. In other words, the loop signal line 32a bypasses the resistor R2.

When the second connector 23 is connected to the first connector 13, one end of the loop signal line 33a is connected to the wiring L3 on the circuit board 10. The other end of the loop signal line 33a is connected to a wiring L4 on the circuit board 10. The wire harness 33 is connected to a signal line (not shown) on the circuit board 10. The circuit board 10 includes a resistor R3 connected in parallel to the loop signal line 33a. In other words, the loop signal line 33a bypasses the resistor R3.

When the second connector 24 is connected to the first connector 14, one end of the loop signal line 34a is connected to the wiring L4 on the circuit board 10. The other end of the loop signal line 34a is connected to a wiring L5 on the circuit board 10. The wiring L5 is grounded. The wire harness 34 is connected to a signal line (not shown) on the circuit board 10. The circuit board 10 includes a resistor R4 connected in parallel to the loop signal line 34a. In other words, the loop signal line 34a bypasses the resistor R4.

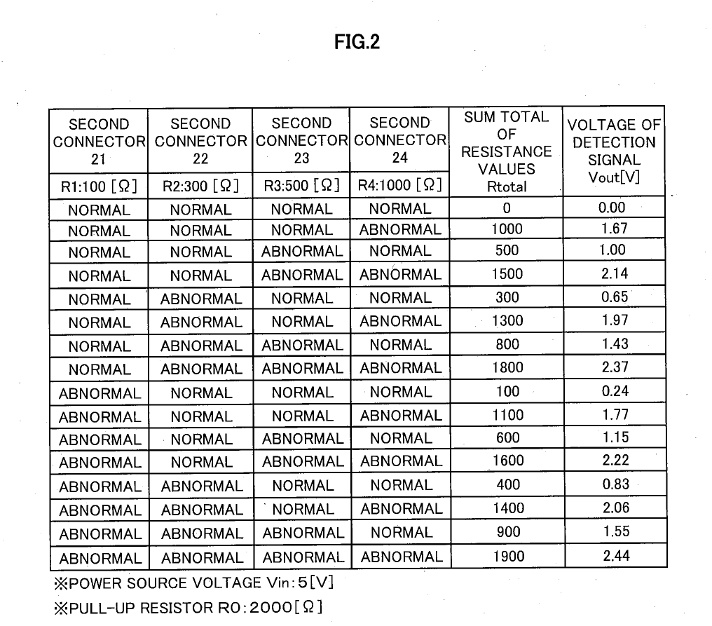

When the second connectors 21 to 24 are connected to the first connectors 11 to 14, the loop signal lines 31a to 34a are connected in series to each other. Besides, the resistors R1 to R4 are connected in series to each other. The resistors R1 to R4 have resistance values different from each other. In this embodiment, as shown in FIG. 2, the resistor R0 is 2000Ω, the resistor R1 is 100Ω, the resistor R2 is 300Ω, the resistor R3 is 500Ω, and the resistor R4 is 1000Ω.

One end of the resistor R0 is connected to a power source, and a specified voltage is applied from the power source. In this embodiment, a power source voltage Vin is 5 V.

When all the second connectors 21 to 24 are connected to the first connectors 11 to 14, a signal (called a detection signal) from the power source passes through the loop signal lines 31a to 34a. The detection signal is used for detecting the connection states of the second connectors 21 to 24 to the first connectors 11 to 14.

A voltage value Vout of the detection signal inputted to a controller 40 is calculated based on the power source voltage Vin and the resistance values of the resistors R0 to R4 through which the detection signal passes. Specifically, the voltage value Vout is calculated based on the following equation (1).

Vout=Rtotal*Vin/(R0+Rtotal) (1)

Here, Rtotal denotes, when the detection signal flows through at least one of the resistors R1 to R4, the sum total of the resistance values of the resistors R1 to R4 through which the detection signal flows.

When the second connector 21 is disconnected from the first connector 11, the detection signal does not flow through the loop signal line 31a, but flows through the resistor R1. The voltage value Vout of the detection signal inputted to the controller 40 is calculated from the power source voltage Vin and the resistance values of the resistors R0 and R1. When only the second connector 21 is disconnected from the first connector 11, the resistance value Rtotal indicated in the equation (1) is the resistance value of the resistor R1.

When the second connector 22 is disconnected from the first connector 12, the detection signal does not flow through the loop signal line 32a, but flows through the resistor R2. The voltage value Vout of the detection signal inputted to the controller 40 is calculated from the power source voltage Vin and the resistance values of the resistors R0 and R2. When only the second connector 22 is disconnected from the first connector 12, the resistance value Rtotal indicated in the equation (1) is the resistance value of the resistor R2.

When the second connector 23 is disconnected from the first connector 13, the detection signal does not flow through the loop signal line 33a, but flows through the resistor R3. The voltage value Vout of the detection signal inputted to the controller 40 is calculated from the power source voltage Vin and the resistance values of the resistors R0 and R3. When only the second connector 23 is disconnected from the first connector 13, the resistance value Rtotal indicated in the equation (1) is the resistance value of the resistor R3.

When the second connector 24 is disconnected from the first connector 14, the detection signal does not flow through the loop signal line 34a, but flows through the resistor R4. The voltage Vout of the detection signal inputted to the controller 40 is calculated from the power source voltage Vin and the resistance values of the resistors R0 and R4. When only the second connector 24 is disconnected from the first connector 14, the resistance value Rtotal indicated in the equation (1) is the resistance value of the resistor R4.

The state where the second connectors 21 to 24 are disconnected from the first connectors 11 to 14 includes a state where the second connectors 21 to 24 are completely disconnected and a state where only part of the second connectors 21 to 24 are disconnected.

FIG. 2 shows a relation between the connection states of the second connectors 21 to 24 and the voltage value Vout of the detection signal inputted to the controller 40. In FIG. 2, “NORMAL” means that the second connectors 21 to 24 are normally connected to the first connectors 11 to 14. Besides, “ABNORMAL” means that the second connectors 21 to 24 are not normally connected to the first connectors 11 to 14. “ABNORMAL” includes a state where, for example, a part of the second connector 21 is disconnected from the first connector 11 and a state where the whole second connector 21 is disconnected from the first connector 11.

As shown in FIG. 2, the voltage values Vout of the detection signals inputted to the controller 40 are different from each other according to the combination of the connection states of the second connectors 21 to 24. Specifically, the resistance values Rtotal are different from each other according to the combination of the connection states of the second connectors 21 to 24. The controller 40 monitors the voltage value Vout of the inputted detection signal, and can specify the connection states in the four second connectors 21 to 24.

The controller 40 uses a map shown in FIG. 2 and specifies a combination of connection states corresponding to the voltage value Vout of the inputted detection signal. For example, when the voltage value Vout of the detection signal is 0.65 V, the controller 40 determines that only the second connector 22 is disconnected from the first connector 12. When the voltage value Vout of the inputted detection signal is 1.15 V, the controller 40 determines that the two second connectors 21 and 23 are disconnected from the first connectors 11 and 13. The map shown in FIG. 2 can be stored in a memory.

In all combinations of the connection states of the second connectors 21 to 24, since the voltage values Vout of the detection signals are different from each other, by only detecting the voltage value Vout, it is possible to easily determine which second connector is not normally connected.

In this embodiment, although the four first connectors 11 to 14 and the four second connectors 21 to 24 are used, the number of the first connectors and the number of the second connectors may be two or more. The resistance values of the resistors provided for the respective second connectors have only to be set so that the voltage values of the detection signals are different from each other in all combinations of the connection states of the second connectors.

A method of setting resistance values of resistors R1 to Rn (n is an integer of 2 or more) will be described.

The resistance values of the resistors R1 to Rn are different from each other. In FIG. 2, the resistance values of the resistors R1 to R4 are different from each other.

When at least two resistance values are arbitrarily selected from n resistance values and the sum total of the resistance values (called a total resistance value) is calculated, the total resistance values in all combinations of the resistance values are different from each other. In FIG. 2, the sum total Rtotal of the resistance values are different from each other in all combinations of the connection states of the second connectors 21 to 24.

The total resistance value is different from the resistance value of each of the resistors R1 to Rn. In FIG. 2, the sum total Rtotal of the resistance values is different from the resistance value of each of the resistors R1 to R4.

When the resistance values of the resistors R1 to Rn are set as in this embodiment, the voltage values Vout of the detection signals can be made different from each other according to the combination of the connection states of the n second connectors.

On the other hand, positions of both ends of the loop signal lines 31a to 34a can be suitably set. In this embodiment, both ends of the loop signal line 31a are positioned at both ends of the second connector 21. Both the ends of the second connector 21 are both the ends of the second connector 21 in an arrangement direction of the wire harness 31. The same as in the loop signal line 31a applies to the loop signal lines 32a to 34a.

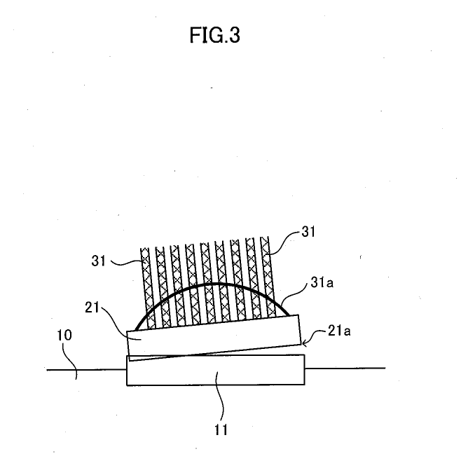

When the second connector 21 is inclined with respect to the first connector 11, a part of the second connector 21 is not normally connected to the first connector 11. When the second connector 21 is inclined with respect to the first connector 11, as shown in FIG. 3, one end 21a of the second connector 21 is most separated from the first connector 11.

As in this embodiment, when both the ends of the loop signal line 31a are positioned at both the ends of the second connector 21, the inclination state of the second connector 21 with respect to the first connector 11 can be reflected in the conduction state of the loop signal line 31a at high accuracy. When the second connector 21 is inclined, one end of the loop signal line 31a becomes liable to be disconnected from the first connector 11, and the inclination state of the second connector 21 can be easily determined.

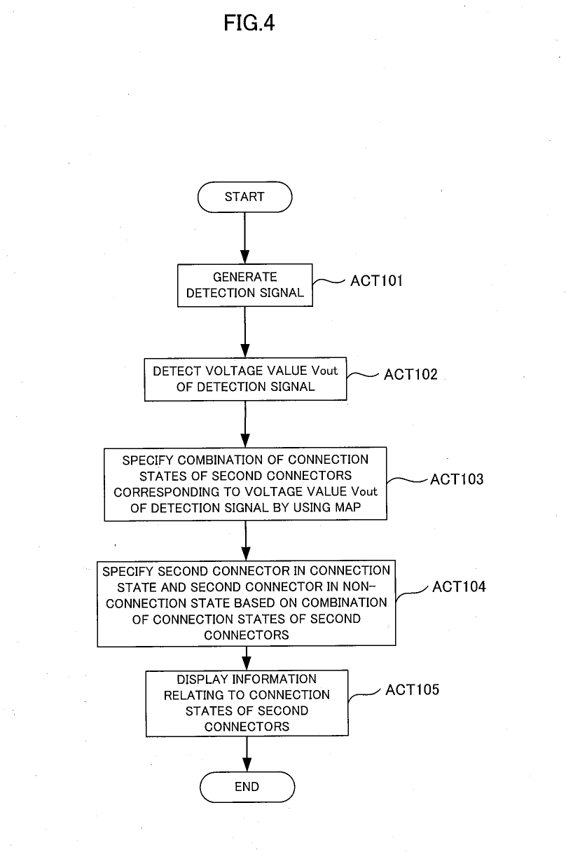

FIG. 4 is a flowchart showing a process for determining the connection states of the second connectors 21 to 24. The process shown in FIG. 4 is realized by causing the controller 40 to execute a program stored in a memory 41. The timing when the process shown in FIG. 4 is performed can be suitably set. In FIG. 1, although the controller 40 incorporates the memory 41, the memory 41 may be provided outside the controller 40.

The controller 40 generates a signal (detection signal) for detecting the connection states of the second connectors 21 to 24 (ACT 101). When the second connectors 21 to 24 are connected to the first connectors 11 to 14, the detection signal flows through the loop signal lines 31a to 34a of the second connectors 21 to 24. When the second connectors 21 to 24 are disconnected from the first connectors 11 to 14, the detection signal flows through the resistors R1 to R4.

The controller 40 detects the voltage value Vout of the detection signal (ACT 102). The voltage value Vout of the detection signal is changed according to a path through which the detection signal flows. That is, as described by use of FIG. 2, the voltage value Vout of the detection signal varies according to the combination of the connection states of the second connectors 21 to 24.

The controller 40 uses the voltage Vout of the detection signal detected at ACT 102 and the map shown in FIG. 2, and specifies the combination of the connection states of the second connectors corresponding to the detected voltage value Vout (ACT 103).

The controller 40 specifies the second connector in a connection state and the second connector in a non-connection state based on the combination of the connection states of the second connectors (ACT 104). The controller 40 causes a display 42 to display information relating to the connection states of the second connectors 21 to 24 (ACT 105). An operator sees the display content of the display 42, and can recognize the second connector in the connection state and the second connector in the non-connection state.

A unit configured to notify the operator of the information relating to the connection states of the second connectors 21 to 24 is not limited to the display on the display 42. For example, the information relating to the connection states of the second connectors 21 to 24 can be notified to the operator by using sound.

In this embodiment, the voltage value Vout is detected, and the combination of the connection states of the second connectors corresponding to the detected voltage value Vout is specified. However, the combination of the connection states of the second connectors can be specified by another method. Specifically, first, the voltage value Vout is detected. Next, the detected voltage value Vout, the power source voltage Vin and the pull-up resistance R0 are substituted into the equation (1), and the total resistance value Rtotal is calculated. When the total resistance value Rtotal is calculated, the map shown in FIG. 2 is used and the combination of the connection states of the second connectors can be specified.

In this embodiment, although the case where the program is previously recorded in the memory 41 is illustrated, the program may be downloaded from a network to the apparatus, or a computer readable recording medium storing the program may be installed in the apparatus.

Any recording medium may be used as long as the recording medium can store a program and can be read by a computer. As the recording medium, for example, an internal storage device mounted inside the computer, such as a ROM or a RAM, a portable recording medium such as a CD-ROM, a flexible disk, a DVD disk, a magneto-optical disk or an IC card, a database to hold a computer program, or another computer and its database, a transmission medium on a line and the like can be enumerated.

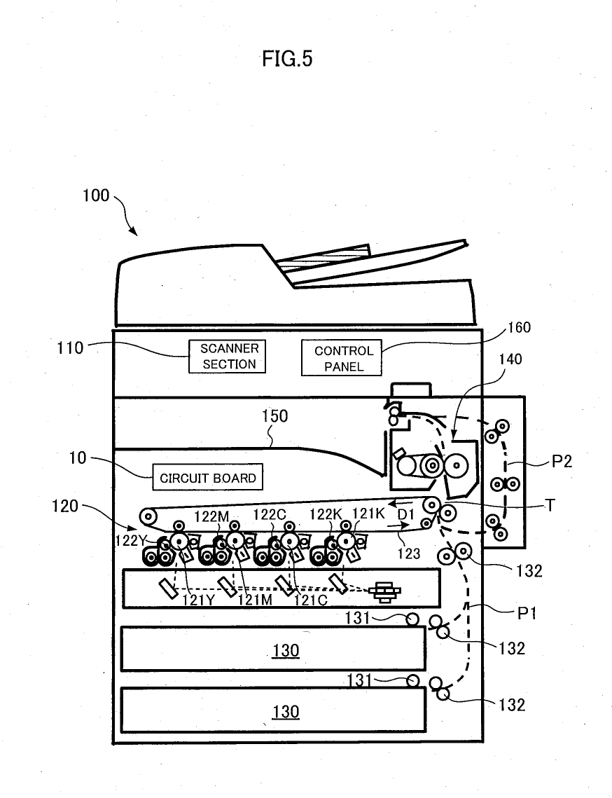

The circuit board 10 can be provided in an image forming apparatus. Specifically, the circuit board 10 can be used as the board for controlling the operation of the image forming apparatus. The image forming apparatus will be described with reference to FIG. 5.

As shown in FIG. 5, an image forming apparatus 100 includes a scanner section 110 and an image forming section 120.

The scanner section 110 scans and reads an image of a sheet document and a book document. The image forming section 120 forms a toner image on a sheet based on image data generated by the reading operation of the scanner section 110 or image data transmitted from an external equipment (for example, a personal computer) to the image forming apparatus 100.

As an example of the process of the image forming apparatus 100, the outline of a copying will be described.

A pickup roller 131 picks up a sheet in a paper feed cassette 130, and the sheet after the pick-up moves along a conveyance path P1. Plural rollers 132 are provided on the conveyance path P1, and the sheet moves by the rotation of the plural rollers 132.

The image forming section 120 forms electrostatic latent images on photoconductive surfaces of photoreceptors 121Y, 121M, 121C and 121K based on the image data generated by the reading operation of the scanner section 110. The photoreceptors 121Y, 121M, 121C and 121K are used for transferring toner images of yellow (Y), magenta (M), cyan (C) and black (K) to the sheet.

Development rollers (so-called mag rollers) 122Y, 122M, 122C and 122K supply toner to the photoreceptors 121Y to 121K on which the electrostatic latent images are formed, and develop the electrostatic latent images formed on the photoconductive surfaces of the photoreceptors 121Y to 121K. The photoreceptors 121Y to 121K transfer toner images formed on the photoconductive surfaces to an intermediate transfer belt 123 (so-called primary transfer). The intermediate transfer belt 123 conveys the toner images by the rotation in an arrow D1 direction, and transfers the toner images on the intermediate transfer belt 123 to the sheet at a secondary transfer position T.

The sheet on which the toner images are transferred moves to a fixing unit 140, and the fixing unit 140 heats the sheet and fixes the toner images to the sheet. The sheet on which the toner images are fixed moves along the conveyance path P1 by the plural rollers and moves to a tray 150. A conveyance path P2 of a sheet is a path for reversing the sheet.

The information relating to the connection states of the second connectors can be displayed on a control panel 160 (corresponding to the display 42). By confirming the display content of the control panel 160, the operator can normally connect the second connector in the non-connection state. The display content of the control panel 160 can be suitably set. It is sufficient if the operator can grasp which second connector is disconnected among the plural second connectors.

In this embodiment, although the description is made on the image forming apparatus for forming an image on a sheet by transferring a toner image, this embodiment can be applied also to an image forming apparatus for forming an image on a sheet by discharging ink.

### Second Embodiment

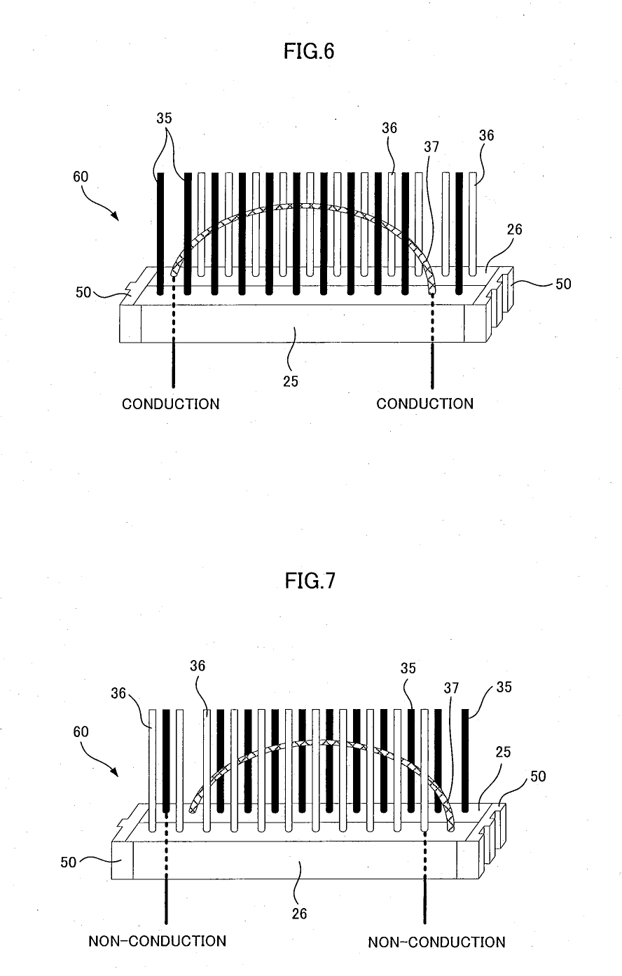

A second embodiment will be described with reference to FIG. 6 and FIG. 7. FIG. 6 and FIG. 7 are outer appearance views of a connector assembly, FIG. 6 shows a state where the connector assembly is normally assembled, and FIG. 7 shows a state where the connector assembly is erroneously assembled. Hereinafter, a point different from the first embodiment will be mainly described.

In this embodiment, a connector assembly 60 includes two second connectors 25 and 26. A pair of holders 50 nip and hold the two second connectors 25 and 26. The second connector 25 includes plural signal lines 35, and the second connector 26 includes plural signal lines 36.

A loop signal line 37 is fixed to the second connectors 25 and 26. Specifically, one end of the loop signal line 37 is connected to one end of the second connector 26. The other end of the loop signal line 37 is fixed to a position adjacent to the signal line 35 provided at one end of the second connector 25.

When the second connectors 25 and 26 in the state shown in FIG. 6 are connected to a corresponding first connector (not shown), both ends of the loop signal line 37 are connected to wirings (corresponding to the wirings L1 to L5 shown in FIG. 1) on the first connector side. The detection signal described in the first embodiment flows through the loop signal line 37.

When the second connectors 25 and 26 in a state shown in FIG. 7 are connected to the corresponding first connector (not shown), both ends of the loop signal line 37 are not connected to the wirings (corresponding to the wirings L1 to L5 shown in FIG. 1) on the first connector side. The detection signal does not flow through the loop signal line 37.

According to this embodiment, when the second connectors 25 and 26 are erroneously assembled, the detection signal does not flow through the loop signal line 37, and it is possible to determine that the assembly of the second connectors 25 and 26 is erroneous.

The fixed positions of the loop signal line 37 to the second connectors 25 and 26 can be suitably set. The positions of both ends of the loop signal line 37 have only to be different between when the second connectors 25 and 26 are normally assembled and when they are erroneously assembled.

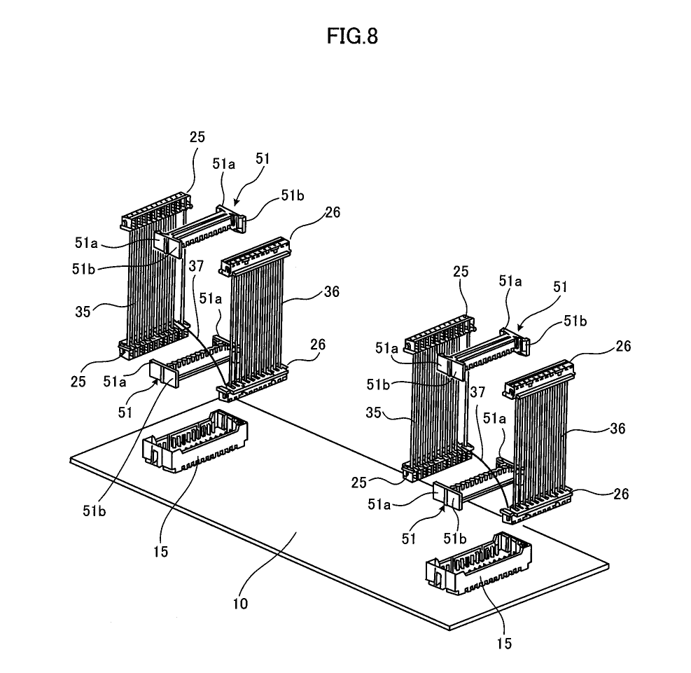

The structure to hold the second connectors 25 and 26 is not limited to the structure shown in FIG. 6 and FIG. 7. For example, the second connectors 25 and 26 can be held by a holder 51 shown in FIG. 8. FIG. 8 is an outer appearance view showing a modified example of this embodiment.

The holder 51 is positioned between the second connectors 25 and 26, and includes a pawl section 51a to hold the second connector 25 and a pawl section 51b to hold the second connector 26. The second connectors 25 and 26 are connected to a first connector 15 on a circuit board 10.

The connector assembly of this embodiment includes the pair of connectors and the holding member to hold the pair of connectors. Each of the connectors is connected to plural signal lines. One end of a detection line is connected to one of the connectors, and the other end of the detection line is connected to the other connector. The connection positions of the detection lines to the respective connectors are different from each other. Here, one end of the detection line is positioned at one end side of the connector assembly, and the other end of the detection line is positioned at the other end side of the connector assembly.

The connector apparatus of this embodiment includes the connector assembly and the connector connected to the connector assembly (pair of connectors). When the pair of connectors are in a normal position, the detection line is connected to a detection circuit. When the pair of connectors are not in the normal position, the detection line is not connected to the detection circuit.

### Third Embodiment

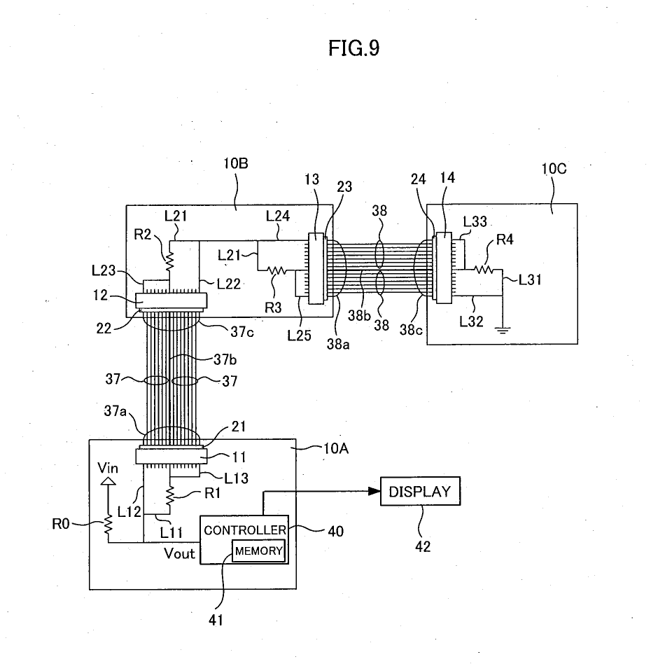

A third embodiment will be described with reference to FIG. 9. FIG. 9 is a view showing a connection structure of a connector in this embodiment. A member having the same function as the member described in the first embodiment is denoted by the same reference numeral and its detailed description is omitted.

A first circuit board 10A includes a first connector 11, and the first connector 11 is connected to wirings L11 to L13. The wiring L11 is provided with a resistor R1. A wire harness 37, a loop signal line 37a and a connection line 37b are connected to a second connector 21 connected to the first connector 11.

When the second connector 21 is connected to the first connector 11, both ends of the loop signal line 37a are connected to the wirings L12 and L13, and the connection line 37b is connected to the wiring L11. The connection line 37b is arranged at the center of the wire harness 37, and is connected to the second connector 21 at a position where distances from both ends of the loop signal line 37a are substantially equal to each other.

The position of the connection line 37b can be suitably set. As in this embodiment, when the connection line 37b is arranged at the center of the wire harness 37, even if only one end of the loop signal line 37a is disconnected from the wiring L12 or the wiring L13, the connection line 37b can be connected to the wiring L11.

When the second connector 21 is connected to the first connector 11, a detection signal flows through the loop signal line 37a and the connection line 37b. When the second connector 21 is completely disconnected from the first connector 11, the detection signal does not flow through the loop signal line 37a and the connection line 37b.

On the other hand, when the second connector 21 is obliquely connected to the first connector 11, one end of the loop signal line 37a is disconnected from the wiring L12 or the wiring L13. When the one end of the loop signal line 37a is disconnected from the wiring L12 or the wiring L13, the detection signal flows through the connection line 37b, and the detection signal does not flow through the loop signal line 37a. That is, the detection signal flows through the resistor R1.

A second circuit board 10B includes a first connector 12, and the first connector 12 is connected to wirings L21 to L23. The wiring L21 is provided with a resistor R2. The wire harness 37, a loop signal line 37c and the connection line 37b are connected to a second connector 22 connected to the first connector 12.

When the second connector 22 is connected to the first connector 12, both ends of the loop signal line 37c are connected to the wirings L22 and L23, and the connection line 37b is connected to the wiring L21. The connection line 37b is connected to the second connector 22 at a position where distances from both ends of the loop signal line 37c are substantially equal to each other.

When the second connector 22 is connected to the first connector 12, the detection signal flows through the loop signal line 37c and the connection line 37b. When the second connector 22 is completely disconnected from the first connector 12, the detection signal does not flow through the loop signal line 37c and the connection line 37b.

On the other hand, when the second connector 22 is obliquely connected to the first connector 12, one end of the loop signal line 37c is disconnected from the wiring L22 or the wiring L23. When the one end of the loop signal line 37c is disconnected from the wiring L22 or the wiring L23, the detection signal flows through the connection line 37b, and the detection signal does not flow through the loop signal line 37c. That is, the detection signal flows through the resistor R2.

The second circuit board 10B includes a first connector 13, and the first connector 13 is connected to wirings L21, L24 and L25. The wiring L21 is provided with a resistor R3. A wire harness 38, a loop signal line 38a and a connection line 38b are connected to a second connector 23 connected to the first connector 13.

When the second connector 23 is connected to the first connector 13, both ends of the loop signal line 38a are connected to the wirings L24 and L25, and the connection line 38b is connected to the wiring L21. The connection line 38b is positioned at the center of the wire harness 38, and is connected to the second connector 23 at a position where distances from both ends of the loop signal line 38a are substantially equal to each other.

The position of the connection line 38b can be suitably set. As in this embodiment, when the connection line 38b is arranged at the center of the wire harness 38, even if only one end of the loop signal line 38a is disconnected from the wiring L24 or the wiring L25, the connection line 38b can be connected to the wiring L21.

When the second connector 23 is connected to the first connector 13, the detection signal flows through the loop signal line 38a and the connection line 38b. When the second connector 23 is completely disconnected from the first connector 13, the detection signal does not flow through the loop signal line 38a and the connection line 38b.

On the other hand, when the second connector 23 is obliquely connected to the first connector 13, one end of the loop signal line 38a is disconnected from the wiring L24 or the wiring L25. When the one end of the loop signal line 38a is disconnected from the wiring L24 or the wiring L25, the detection signal flows through the connection line 38b, and the detection signal does not flow through the loop signal line 38a. That is, the detection signal flows through the resistor R3.

A third circuit board 10C includes a first connector 14, and the first connector 14 is connected to wirings L31 to L33. The wiring L31 is provided with a resistor R4, and one end of the wiring L31 is grounded. The wire harness 38, a loop signal line 38c and the connection line 38b are connected to a second connector 24 connected to the first connector 14.

When the second connector 24 is connected to the first connector 14, both ends of the loop signal line 38c are connected to the wirings L32 and L33, and the connection line 38b is connected to the wiring L31. The connection line 38b is connected to the second connector 24 at a position where distances from both ends of the loop signal line 38c are substantially equal to each other.

When the second connector 24 is connected to the first connector 14, the detection signal flows through the loop signal line 38c and the connection line 38b. When the second connector 24 is completely disconnected from the first connector 14, the detection signal does not flow through the loop signal line 38c and the connection line 38b.

On the other hand, when the second connector 24 is obliquely connected to the first connector 14, one end of the loop signal line 38c is disconnected from the wiring L32 or the wiring L33. When the one end of the loop signal line 38c is disconnected from the wiring L32 or the wiring L33, the detection signal flows through the connection line 38b, and the detection signal does not flow through the loop signal line 38c. That is, the detection signal flows through the resistor R4.

In this embodiment, when the second connectors 21 to 24 are disconnected from the first connectors 11 to 14, a voltage value Vout of the detection signal inputted to a controller 40 is calculated from a power source voltage Vin and a resistance value of a resistor R0.

When only a part of the second connector 21 is connected to the first connector 11, and the second connectors 22 to 24 are completely connected to the first connectors 12 to 14, since the detection signal flows through the resistor R1, the voltage value Vout of the detection signal inputted to the controller 40 is calculated from the power source voltage Vin and the resistance values of the resistors R0 and R1.

When only a part of the second connector 22 is connected to the first connector 12 and the second connectors 21, 23 and 24 are completely connected to the first connectors 11, 13 and 14, since the detection signal flows through the resistor R2, the voltage value Vout of the detection signal inputted to the controller 40 is calculated from the power source voltage Vin and the resistance values of the resistors R0 and R2.

Only a part of the second connector 23 is connected to the first connector 13, and the second connectors 21, 22 and 24 are completely connected to the first connectors 11, 12 and 14, since the detection signal flows through the resistor R3, the voltage value Vout of the detection signal inputted to the controller 40 is calculated from the power source voltage Vin, and the resistance values of the resistors R0 and R3.

Only a part of the second connector 24 is connected to the first connector 14, and the second connectors 21 to 23 are completely connected to the first connectors 11 to 13, since the detection signal flows through the resistor R4, the voltage value Vout of the detection signal inputted to the controller 40 is calculated from the power source voltage Vin and the resistance values of the resistors R0 and R4.

Also in this embodiment, the resistance values of the resistors R1 to R4 are set similarly to those of the first embodiment. Thus, the voltage value Vout of the detection signal inputted to the controller 40 varies according to the combination when the respective second connectors (21 to 24) and the respective first connectors (11 to 14) are only partially connected to each other. Similarly to FIG. 2 described in the first embodiment, the voltage values Vout can be made different from each other.

In this embodiment, “NORMAL” shown in FIG. 2 indicates the state where the respective second connectors (21 to 24) are completely connected to the respective first connectors (11 to 14). Besides, “ABNORMAL” shown in FIG. 2 indicates the state where the respective second connectors (21 to 24) are only partially connected to the respective first connectors (11 to 14), and indicates the state where the connection lines 37b and 38b are connected.

According to this embodiment, the connection state of the second connectors (21 to 24) to the first connectors (11 to 14) can be determined by detecting the voltage value Vout. Specifically, it is possible to determined whether all the second connectors are completely connected to the corresponding first connectors. Besides, the second connector which is only partially connected to the first connector can be specified.

On the other hand, as described in the first embodiment, the second connector which is only partially connected to the first connector can also be specified by calculating the total resistance value.

While certain embodiments have been described, these embodiments have been presented by way of example only, and are not intended to limit the scope of invention. Indeed, the novel apparatus and methods described herein may be embodied in a variety of other forms; furthermore, various omissions, substitutions and changes in the form of the apparatus and methods described herein may be made without departing from the sprit of the inventions. The accompanying claims and their equivalents are intended to cover such forms or modifications as would fall within the scope and spirit of the inventions.

What is claimed is:

1. An apparatus configured to detect connection states of connectors, comprising:
a plurality of resistors having resistance values different from each other and connected in series to each other, in which sums of at least two resistance values selected from the plurality of resistance values are different from each other in all combinations of the plurality of resistance values, and are different from the resistance value of each of the resistors;
a plurality of first connectors provided correspondingly to the respective resistors;
a plurality of second connectors connected to the first connectors and including bypass lines which bypass the respective resistors when the second connectors are connected to the first connectors; and
a controller to detect connection states of the second connectors to the first connectors based on a voltage value of a detection signal flowing through the resistors and the bypass lines.

2. The apparatus of claim 1, wherein the voltage value of the detection signal varies according to the connection states of the plurality of second connectors.

3. The apparatus of claim 1, further comprising a memory storing a map indicating a relation between the connection states of the plurality of second connectors and the voltage value of the detection signal.

4. The apparatus of claim 3, wherein the controller detects the voltage value of the detection signal, and uses the map to specify the connection states of the second connectors corresponding to the detected voltage value.

5. The apparatus of claim 1, further comprising a memory storing a map indicating a relation between the connect ion states of the plurality of second connectors and the sum of the resistance values.

6. The apparatus of claim 5, wherein the controller detects the voltage value of the detection signal, calculates, based on the detected voltage value, the sum of the resistance values of the resistors through which the detection signal flows, and uses the map to specify the connection states of the second connectors corresponding to the calculated sum of the resistance values.

7. The apparatus of claim 1, further comprising a circuit board including the plurality of first connectors.

8. The apparatus of claim 1, wherein each of the second connectors is fixed to a plurality of signal lines.

9. The apparatus of claim 1, further comprising an information output unit to output information relating to the connection states of the second connectors.

10. The apparatus of claim 9, wherein the information output unit is a display to display the information relating to the connection states of the second connectors.

11. The apparatus of claim 1, wherein both ends of the bypass line are positioned at both ends of the second connector.

12. The apparatus of claim 1, wherein
one end of a resistor circuit including the plurality of resistors is grounded, and the other end is connected to a pull-up resistor, and
the controller is connected between the resistor circuit and the pull-up resistor.

13. An image forming apparatus, comprising:
an image forming section to form an image on a sheet; and
an apparatus to detect connection states of connectors, transmits control information of the image forming section through a first connectors and a second connectors, and comprise a plurality of resistors having resistance values different from each other and connected in series to each other, in which sums of at least two resistance values selected from the plurality of resistance values are different from each other in all combinations of the plurality of resistance values, and are different from the resistance value of each of the resistors, a plurality of first connectors provided correspondingly to the respective resistors, a plurality of second connectors connected to the first connectors and including bypass lines which bypass the respective resistors when the second connectors are connected to the first connectors, and a controller to detect connection states of the second connectors to the first connectors based on a voltage value of a detection signal flowing through the resistors and the bypass lines.

14. A method of detecting connection states of connectors, comprising:
outputting a detection signal to a plurality of resistors which are connected in series to each other and have resistance values different from each other and in which sums of at least two resistance values selected from the plurality of resistance values are different from each other in all combinations of the plurality of resistance values and are different from the resistance value of each of the resistors;
flowing the detection signal, when second connectors are connected to first connectors corresponding to the respective resistors, through bypass lines of the second connectors to bypass the respective resistors; and
detecting connection states of the second connectors by using a voltage value of the detection signal which varies according to the connection states of the second connectors to the first connectors.

15. The method of claim 14, further comprising using a map to specify the connection states of the second connectors, the map indicating a relation between the connection states of the plurality of second connectors and the voltage value of the detection signal.

16. The method of claim 15, further comprising
detecting the voltage value of the detection signal, and
using the map to specify the connection states of the second connectors corresponding to the detected voltage value.

17. The method of claim 14, further comprising using a map to detect the connection states of the second connectors, the map indicating a relation between the connection states of the plurality of second connectors and the sums of the resistance values.

18. The method of claim 17, further comprising
detecting the voltage value of the detection signal,
calculating, based on the detected voltage value, the sum of the resistance values of the resistors through which the detection signal flows, and
using the map to specify the connection states of the second connectors corresponding to the calculated sum of the resistance values.

19. The method of claim 14, further comprising outputting information relating to the connection states of the second connectors.

20. The method of claim 19, further comprising displaying the information relating to the connection states of the second connectors.
